(19) United States
(12) Patent Application Publication
(10) Pub. No.: US 2013/0152850 A1
(43) Pub. Date: Jun. 20, 2013

(54) METHOD AND APPARATUS FOR MONITORING AND CONTROLLING CRYSTAL GROWTH, AND PROBE SYSTEM

(71) Applicants: Chia-Ying Hsieh, New Taipei City (TW); Chi-Hao Chang, New Taipei City (TW); Hsin-Hwa Hu, New Taipei City (TW)

(72) Inventors: Chia-Ying Hsieh, New Taipei City (TW); Chi-Hao Chang, New Taipei City (TW); Hsin-Hwa Hu, New Taipei City (TW)

(21) Appl. No.: 13/556,082

(22) Filed: Jul. 23, 2012

(30) Foreign Application Priority Data
Dec. 16, 2011 (TW) 100146828

(51) Int. Cl. C30B 19/10

(52) U.S. Cl. 117/55; 117/202

(57) ABSTRACT

In a method for monitoring and controlling crystal growth during a crystal growing procedure, heights of a plurality of measuring points on a solid-liquid interface of a crystal material disposed in a crucible are measured, and at least one parameter of the crystal growing procedure is optimized based on the measured heights, so that the solid-liquid interface maintains a dome shape with a predetermined curvature during the crystal growing procedure.

### CROSS-REFERENCE TO RELATED APPLICATION

This application claims priority of Taiwanese Application No. 100146.828, filed on Dec. 16, 2011.

### BACKGROUND OF THE INVENTION

1. Field of the Invention

The invention relates to a method and an apparatus for growing crystal, more particularly to a method and an apparatus for monitoring and controlling crystal growth during a crystal growing procedure.

2. Description of the Related Art

Mono-like silicon is a crystal material that can be applied to a solar cell for converting solar energy to electrical energy. Compared with other conventional crystal materials, namely single-crystal silicon and polycrystalline silicon (polysilicon), the mono-like silicon has a relatively low manufacturing cost compared to single-crystal silicon, and a relatively high energy conversion efficiency than polysilicon.

The mono-like silicon is typically manufactured through a crystal growing procedure. Quality of the crystal of mono-like silicon is a major factor that affects energy conversion efficiency. However, when monitoring and controlling crystal growth during the conventional crystal growing procedure are not available, parameters of the crystal growing procedure cannot be adjusted during the conventional crystal growing procedure. Therefore, the parameters must be adjusted after the crystal growing procedure is finished, based on the result of the previous crystal growing procedure. In order to optimize the parameters, many crystal growing procedures may have to be executed.

Monitoring the crystal growing procedure typically involves obtaining heights of different points on a solid-liquid interface of the crystal material. Conventionally, a probe is manually extended into a crucible for contacting the solid-liquid interface of the crystal material therein, and the state of crystal growth is determined empirically. Establishment of an objective standard of determination is preferable.

### SUMMARY OF THE INVENTION

Therefore, the object of the present invention is to provide a method that is capable of monitoring and controlling crystal growth, and that can increase productivity and improve crystal quality.

Accordingly, a method of the present invention is for monitoring and controlling crystal growth during a crystal growing procedure. The method comprises the following steps of:

measuring heights of a plurality of measuring points on a solid-liquid interface of a crystal material disposed in a crucible; and

automatically optimizing at least one parameter of the crystal growing procedure based on the measured heights, so that the solid-liquid interface maintains a dome shape with a predetermined curvature during the crystal growing procedure.

Another object of the present invention is to provide an apparatus for implementing the aforementioned method.

Accordingly, an apparatus of the present invention is for monitoring and controlling crystal growth during a crystal growing procedure. The apparatus comprises a growth chamber, a crucible, a heating system, a probe system and a control system.

The crucible is disposed in the growth chamber for receiving a crystal material therein. The heating system is disposed in the growth chamber and arranged around the crucible. The probe system is disposed at the growth chamber and includes a probe extended into the crucible for contacting a solid-liquid interface of the crystal material in the crucible during the crystal growing procedure so as to obtain crystal growth information.

The control system is coupled to the probe system for receiving the crystal growth information therefrom. The control system is further coupled to the heating system for automatically controlling heating operation of the heating system according to the crystal growth information received from the probe system.

Still another object of the present invention is to provide a probe system for monitoring crystal growth during the crystal growing procedure.

Accordingly, a probe system of the present invention is for monitoring crystal growth during a crystal growing procedure in a crucible. The probe system comprises a probe and a probe control mechanism.

The probe has a main portion and a probing portion connected to the main portion and to be extended into the crucible. The main portion is movable along a predetermined measuring track and is rotatable around an axis of the main portion. The probing portion has a tip which is offset from the axis of the main portion and which is disposed for contacting a solid-liquid interface of crystal material in the crucible during the crystal growing procedure.

The probe control mechanism is connected to the probe for raising and lowering the probe relative to the crucible. The probe control mechanism is further for controlling movement of the main portion of the probe along the predetermined measuring track and rotation of the main portion around the axis of the main portion so that the tip is able to contact different points on the solid-liquid interface.

### BRIEF DESCRIPTION OF THE DRAWINGS

Other features and advantages of the present invention will become apparent in the following detailed description of the preferred embodiment with reference to the accompanying drawings, of which:

FIG. 1 is a flowchart of a preferred embodiment of a method for monitoring and controlling crystal growth during a crystal growing procedure, according to the present invention;

FIG. 2 is a schematic diagram of an implementation of an apparatus for monitoring and controlling crystal growth during a crystal growing procedure, according to the present invention;

FIG. 3 is a perspective view of a probe system of the implementation;

FIG. 4 is a schematic view illustrating a probe of the probe system moving in a crucible;

FIG. 5 is a side view of the probe system;

FIG. 6 is schematic diagram of another implementation of an apparatus according to the present invention;

FIG. 7 is a schematic view illustrating arrangement of a plurality of probes of the probe system in the implementation of FIG. 6; and

FIG. 8 is a schematic diagram illustrating the apparatus being utilized in other procedures.

### DETAILED DESCRIPTION OF THE PREFERRED EMBODIMENT

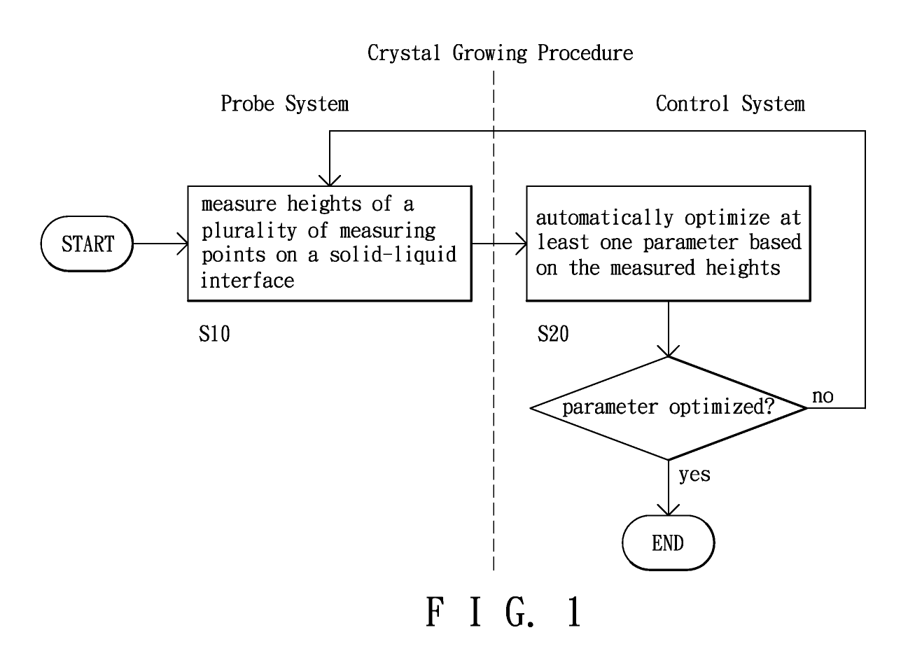

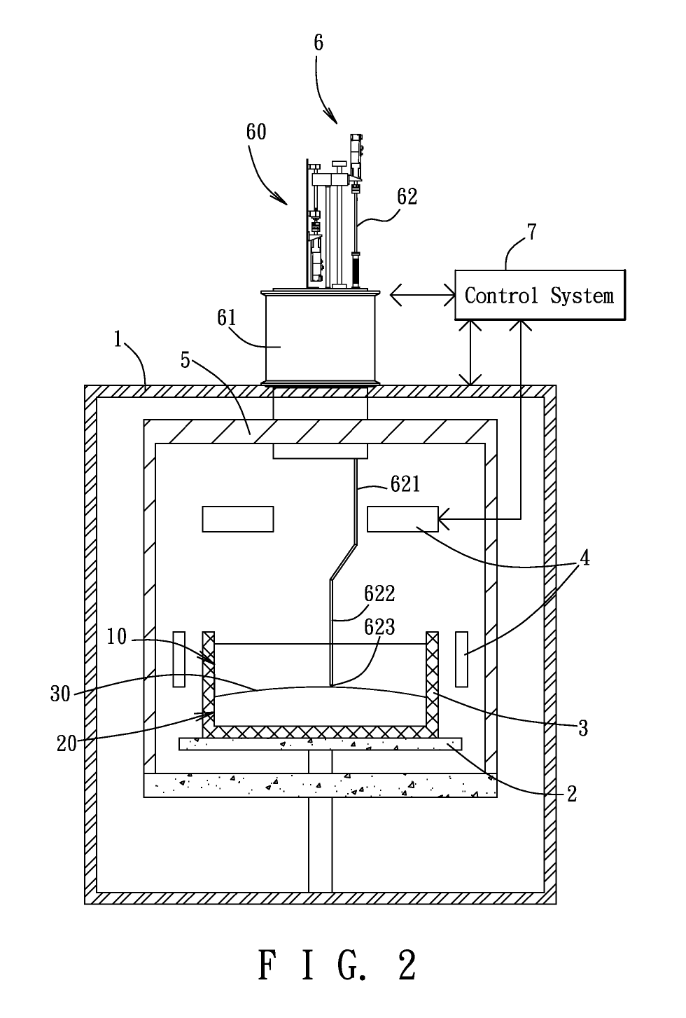

FIG. 1 illustrates the preferred embodiment of a method for monitoring and controlling crystal growth during a crystal growing procedure according to the present invention. Generally, during the crystal growing procedure, crystal material is disposed in a crucible and melted. Afterward, a crystal ingot is grown from the melted crystal material using directional solidification techniques. In step S10, heights of a plurality of measuring points on a solid-liquid interface of the crystal material are measured using a probe system 6 (see FIG. 2). Taking a G5 6-inch wafer crucible as an example, the measuring points can be designated by using the center of the crucible as the center of a circle with a radius of 390 mm, and selecting four points that are arranged evenly on the circumference of the circle. The probe system 6 is operable to obtain crystal growth information that includes measured heights of the measuring points, and to transmit the crystal growth information to a control system 7 that is coupled to the probe system 6.

Then, in step S20, the control system 7 is operable to calculate the shape of the solid-liquid interface of the crystal material based on the crystal growth information, and to automatically adjust at least one parameter of the crystal growing procedure, so that the solid-liquid interface maintains a dame shape with a predetermined curvature during the crystal growing procedure. In this embodiment, the parameter may be a heating power, a rate of air inflow into a growth chamber, a temperature of cooling water, etc.

Afterward, the flow goes back to step S10, where the probe system 6 is operable to further obtain new crystal growth information in real time after the parameter is adjusted. The new crystal growth information is similarly transmitted to the control system 7 for further shape recalculation, and for subsequently determining whether the parameter requires further adjustment. The aforesaid procedure is thus executed repeatedly until the parameter is optimized, and subsequently the solid-liquid interface maintains the dome shape with the predetermined curvature.

The effect of maintaining the solid-liquid interface to have the dome shape with the predetermined curvature is that, since height of a central part of the solid-liquid interface is higher than that of an outer part of the solid-liquid interface, impurities of the crystal material move to the lower outer part of the solid-liquid interface. Therefore, the central part of grown crystal yields higher purity than the outer part, and can be separated from the outer part so as to obtain a large chunk of crystal with high purity.

The above method can be implemented using either of the following two implementations of an apparatus, which will now be described in detail.

As shown in FIG. 2, a first implementation of an apparatus for monitoring and controlling crystal growth according to this invention comprises a growth chamber 1, a platform 2, a crucible 3, a heating system 4, a cage 5, a probe system 6, and a control system 7. The platform 2, the crucible 3, the heating system 4 and the cage 5 are disposed in the growth chamber 1. The crucible 3 is disposed on top of the platform 2 and is covered by the cage 5, and the crystal material is disposed in the crucible 3 fox growing crystal. The heating system 4 is arranged around the crucible 3 and inside the cage 5. The cage 5 is operable to be lowered so as to cover the crucible 3 and the heating system 4. The heating system 4 can be actuated to heat the crucible 3, melting the crystal material therein to obtain molten crystal material 10. The cage 5 is operable to be raised when the crystal material is completely melted, so that a bottom part of the crucible 3 strats to cool, thereby solidifying the crystal material located in the bottom part of the crucible 3 to obtain solid crystal 20, and creating a solid-liquid interface 30.

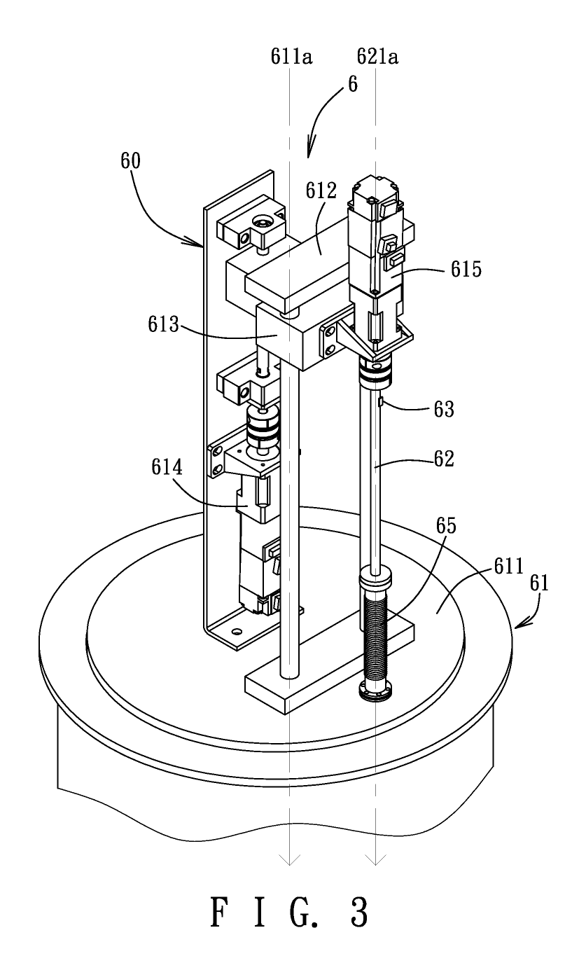

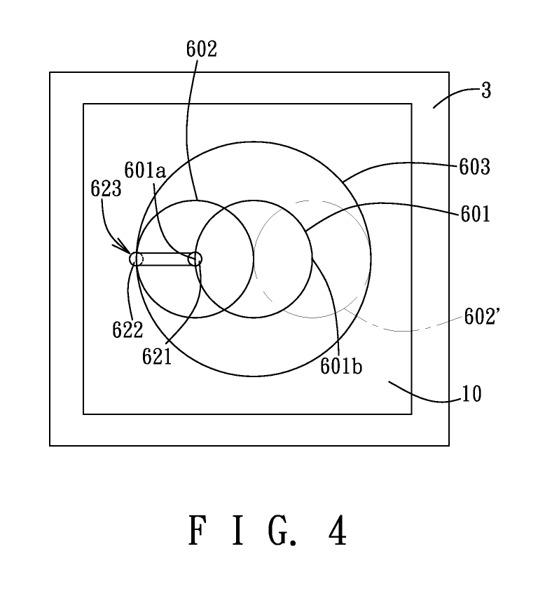

Further referring to FIGS. 3 and 4, the probe system 6 includes a probe control mechanism 60 and a probe 62.

In this embodiment, the probe control mechanism 60 is disposed at the growth chamber 1 and has a probe seal 61, and the probe 62 is connected to a rotatable inner cylinder 611 of the probe seal 61. The rotatable inner cylinder 611 is driven by a driving motor (not shown) of the control system 7 so as to be rotatable around a rotary axis 611a. The probe 62 has a main portion 621 and a probing portion 622 that is bent from the main portion 621 and that is to be extended into the crucible 3 for contacting the solid-liquid interface 30. The probing portion 622 has a tip 623 which is driven by the main portion 621 to move in the crucible 3 for contacting different points on the solid-liquid interface 30. Specifically, FIG. 4 shows that the tip 623 of the probing portion 622 is offset from an axis 621a of the main portion 621. Furthermore, the main portion 621 is movable along a predetermined measuring track 601 when the inner cylinder 611 rotates and is rotatable around the axis 621a, which is offset from the rotary axis 611a. In such configuration, when the inner cylinder 611 rotates around the rotary axis 611a, the main portion 621 is driven to move along the predetermined measuring track 301. When the main portion 621 is located at a point 601a of the measuring track 601, the tip 623 of the probing portion 622 is driven by the rotational movement of the main portion 621 around the axis 621a and is moved along a probing track 602. Similarly, when the main portion 621 moves to another point 601b of the predetermined measuring track 601, the rotational movement of the main portion 621 around the axis 621a drives the probing portion 622 to move along another probing track 602′. In such manner, the measuring points of the solid-liquid surface 30 to be contacted by the tip 623 are within a circular measuring range 603. A desired diameter of the circular measuring range 603 can be obtained by adjusting a distance between the axes 611a, 621a and a distance between the tip 623 and the axis 621a, for adapting to crucibles 3 of various sizes.

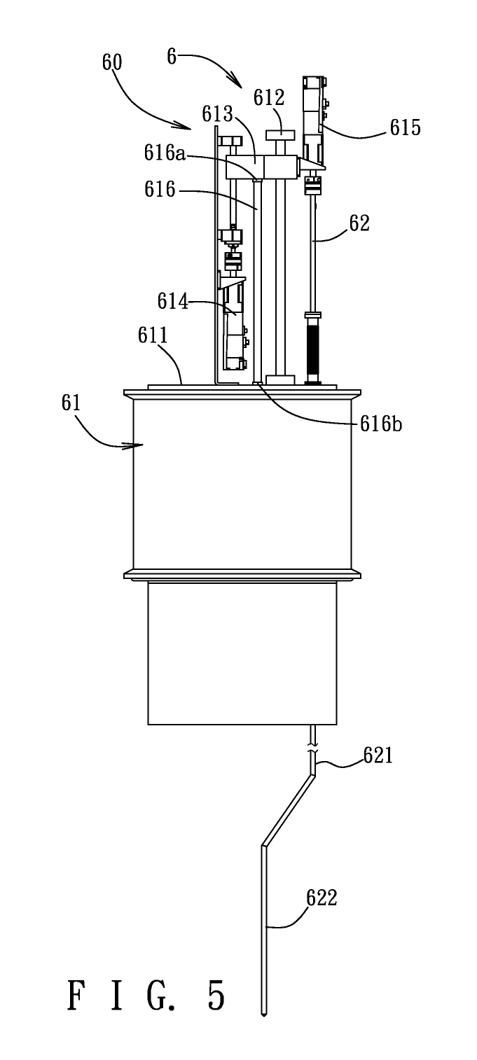

FIGS. 3 and 5 illustrate the probe system 6 in greater detail. Preferably, the probe system 6 further includes a force sensor 63 disposed on the probe 62. The force sensor 63 is for determining whether the tip 623 of the probe 62 comes into contact with the solid-liquid interface 30, and can be a strain gauge or a load cell. Specifically, the force sensor 63 is operable to sense pressure change on the tip 623 for determining whether the tip 623 of the probe 62 comes into contact with the solid-liquid interface 30. In this implementation, the strain gauge serves as the force sensor 63. The probe control mechanism 60 further includes a guiding component 612, a sliding component 613, an elevating motor 614, a rotating motor 615 and a position measuring device 616.

The guiding component 612 is disposed on the probe seal 61 and disposed parallel to the probe 62. The sliding component 613 is slidably disposed on the guiding component 612 and connected to the probe 62.

The elevating motor 614 is disposed on the rotatable inner cylinder 611 of the probe seal 61 and connected to the sliding component 641 for controlling raising and lowering of the probe 62 relative to the crucible 3. The rotating motor 615 is disposed on the sliding component 613 and is connected to the probe 62 for controlling rotation of the main portion 621 of the probe 62 around the axis 621a, such that the tip 623 is driven to move within the circular measuring range 603 and to contact different points of the solid-liquid interface 30. The position measuring device 616 is connected to the probe seal 61 and the sliding component 613, and is for measuring vertical displacement of the probe 62. In this implementation, the position measuring device 616 is a displacement transducer, and can be an optical scale in other implementations. The position measuring device 616 has a retractable end 616a connected to the sliding component 613 and a fixed end 616b connected to the rotatable inner cylinder 611 of the probe seal 61. The position measuring device 616 is operable to measure the vertical displacement of the sliding component 613 relative to the probe seal 61, and subsequently the vertical displacement of the probe 62. In this implementation, the probe 62 is sleeved by a retractable tube 65 for sealing gaps between the probe 62 and the probe seal 61.

Referring back to FIG. 2, the control system 7 is coupled to the heating system 4, the cage 5 and the probe system 6 for controlling the parameters of the crystal growth procedure and the operation of the apparatus. During the crystal growth procedure, the control system 7 is operable to rotate the rotatable inner cylinder 611 around the rotary axis 611a, and to control the rotating motor 615 in order to control the probing portion 622 of the probe 62 for moving among different measuring points on the solid-liquid interface 30. When the probing portion 622 of the probe 62 is moved to a specific measuring point, the control system 7 is operable to actuate the elevating motor 614 for lowering the probing portion 622. The probing portion 622 is lowered until the force sensor 63 determines that the tip 623 has come into contact with the solid-liquid interface 30. The position measuring device 616 is operable to simultaneously determine the vertical displacement of the probe 62 in order to obtain the crystal growth information, and to transmit the crystal growth information to the control system 7. This probing procedure can be repeated multiple times for obtaining respectively the crystal growth information of multiple measuring points, and the shape of the solid-liquid interface 30 can be calculated based on the crystal growth information thereof. The control system 7 is then operable to automatically optimize the parameters of the crystal growing procedure. The parameters may include a raising speed of the cage 5, a power of the heating system 4, a rate of air inflow into the growth chamber 1, etc., and are optimized by the control system 7 so that the solid-liquid surface 30 maintains a dome shape with a predetermined curvature during the crystal growing procedure.

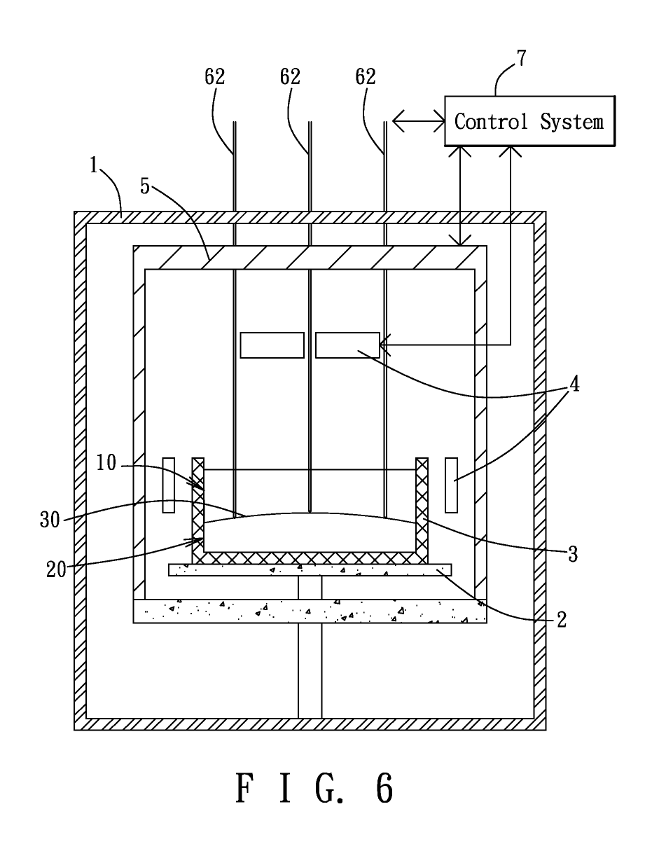

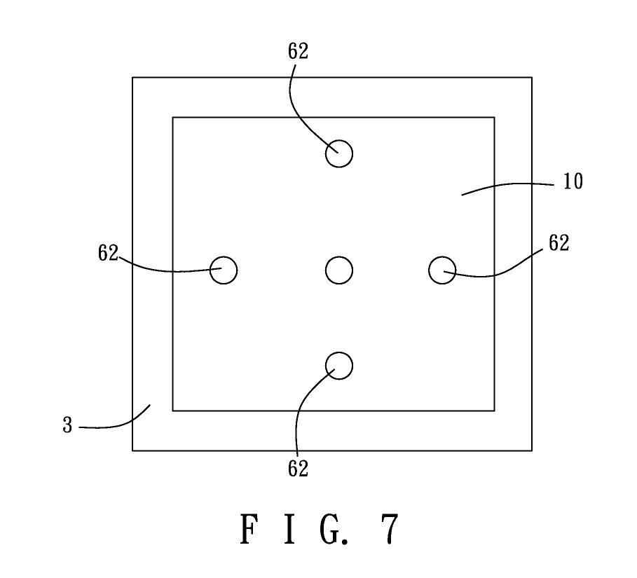

FIG. 6 illustrates another implementation of the apparatus according to the present invention. The main difference between this implementation and the previous one is that in this implementation, the probe system 6 includes a plurality of fixed probes 62. Each of the probes 62 is for probing one of the predetermined measuring points. An elevating mechanism (not shown) similar to that of the previous implementation is operable to control raising and lowering of the probes 62 relative to the crucible 3. In this implementation, five probes 62 are disposed to obtain crystal growth information of five measuring points (see FIG. 7).

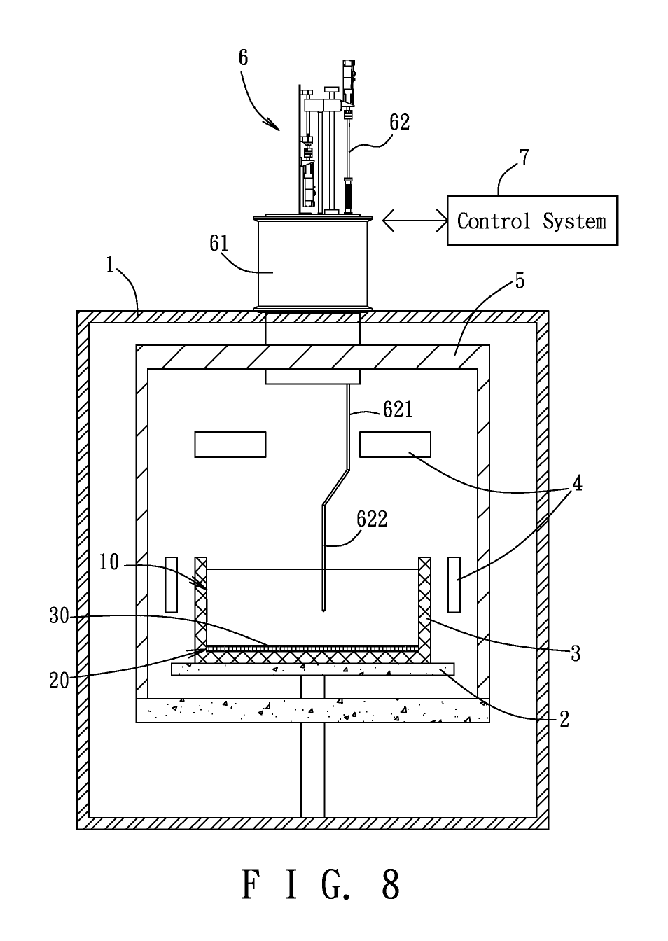

In addition to the aforementioned effects, the probe system 6 can be operable to further detect other states of the crystal growth procedure, such as a rate that the crystal material melts, a rate that the crystal grows, and whether the crystal growth procedure has been completed. Furthermore, the probe system 6 is operable for detecting procedures other than the crystal growth procedure. For example, before a crystal growth procedure for growing mono-like silicon, a melting procedure is first executed as shown in FIG. 8. A mono crystal material is disposed in the crucible 3 (i.e., the solid crystal 20 in FIG. 8, with a thickness for 3 cm), and covered with a layer of silicon material. The silicon is first heated and melted, in turn melting the top portion of the mono crystal material (thus becoming the molten crystal material 10) and creating the solid-liquid interface 30. The probe system 6 is then operable to detect the height of the solid-liquid interface 30, and to allow the control system 7 to control the melting procedure. For instance, when the probe system 6 determines that the height of the solid-liquid interface 30 is lower than a threshold (e.g., 1.5 cm), the control system 7 is operable to terminate the melting procedure. Such effect can be achieved by both of the aforementioned implementations.

To sum up, the method of this invention enables the crystal growing procedure to be monitored and controlled automatically, such that the solid-liquid surface 30 can Maintain a dome shape with a predetermined curvature during the crystal growing procedure. As a result, crystal with a better yield may be obtained.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A method for monitoring and controlling crystal growth during a crystal growing procedure, comprising the following steps of:
(a) measuring heights of a plurality of measuring points on a solid-liquid interface of a crystal material disposed in a crucible; and
(b) automatically optimizing at least one parameter of the crystal growing procedure based on the measured heights, so that the solid-liquid interface maintains a dome shape with a predetermined curvature during the crystal growing procedure.

2. The method as claimed in claim 1, wherein, in step (a), a plurality of probes are used to measure the heights of the measuring points, respectively.

3. The method as claimed in claim 1, wherein, in step (a), a probe is moved in an automated manner to different points on the solid-liquid interface to measure the heights of the measuring points, respectively.

4. The method as claimed in claim 3, wherein, in step (a), the probe includes a main portion and a probing portion connected to the main portion, the main portion being movable along a predetermined measuring track and being rotatable around an axis thereof, the probing portion having a tip which is offset from the axis of the main portion and which is disposed for contacting the different points on the solid-liquid interface when the main portion is rotated around the axis of the main portion and is moved along the predetermined measuring track.

5. The method as claimed in claim 1, wherein, in step (b), said at least one parameter includes a heating power during the crystal growing procedure.

6. An apparatus for monitoring and controlling crystal growth during a crystal growing procedure, comprising:
a growth chamber;
a crucible disposed in said growth chamber for receiving a crystal material therein;
a heating system disposed in said growth chamber and arranged around said crucible;
a probe system disposed at said growth chamber and including a probe extended into said crucible for contacting a solid-liquid interface of the crystal material in said crucible during the crystal growing procedure so as to obtain crystal growth information; and
a control system coupled to said probe system for receiving the crystal growth information therefrom and to said heating system for automatically controlling heating operation of said heating system according to the crystal growth information received from said probe system.

7. The apparatus as claimed in claim 6, wherein said probe system further includes a force sensor disposed on said probe for determining whether a tip of said probe comes into contact with the solid-liquid interface.

8. The apparatus as claimed in claim 7, wherein said force sensor includes at least one of a strain gauge and a load cell.

9. The apparatus as claimed in claim 6, wherein said probe system further includes a probe control mechanism connected to said probe for raising and lowering said probe relative to said crucible.

10. The apparatus as claimed in claim 9, wherein said probe includes a main portion and a probing portion connected to said main portion and extended into said crucible, said main portion being driven by said probe control mechanism to move along a predetermined measuring track and to rotate around an axis of said main portion, said probing portion having a tip which is offset from the axis of said main portion and which is disposed for contacting the solid-liquid interface, said tip being able to contact different points on the solid-liquid interface when said probe is driven by said probe control mechanism.

11. The apparatus as claimed in claim 10, wherein said probe control mechanism includes a probe seal attached to said growth chamber and connected to said probe, said probe seal being rotatable around a rotary axis, the axis of said main portion of said probe being offset from the rotary axis to result in movement of said main portion along the predetermined measuring track when said probe seal rotates.

12. The apparatus as claimed in claim 11, wherein said probe control mechanism further includes:
a guiding component disposed on said probe seal and disposed parallel to said probe;
a sliding component slidably disposed on said guiding component and connected to said probe;
an elevating motor disposed on said probe seal and connected to said sliding component for controlling raising and lowering of said probe; and
a rotating motor disposed on said sliding component and connected to said probe for controlling rotation of said main portion of said probe around the axis of said main portion.

13. The apparatus as claimed in claim 12, wherein said probe control mechanism further includes a position measuring device for measuring vertical displacement of said probe.

14. The apparatus as claimed in claim 13, wherein said position measuring device is connected to said probe seal and said sliding component and is configured to measure the vertical displacement of said probe by measuring vertical displacement of said sliding component relative to said probe seal.

15. A probe system for monitoring crystal growth during a crystal growing procedure in a crucible, comprising:
a probe having a main portion and a probing portion connected to said main portion and to be extended into the crucible, said main portion being movable along a predetermined measuring track and being rotatable around an axis of said main portion, said probing portion having a tip which is offset from the axis of said main portion and which is disposed for contacting a solid-liquid interface of crystal material in the crucible during the crystal growing procedure; and
a probe control mechanism connected to said probe for raising and lowering said probe relative to the crucible and for controlling movement of said main portion of said probe along the predetermined measuring track and rotation of said main portion around the axis of said main portion so that said tip is able to contact different points on the solid-liquid interface.

16. The probe system as claimed in claim 15, further comprising a force sensor disposed on said probe for determining whether said tip of said probing portion comes into contact with the solid-liquid interface.

17. The probe system as claimed in claim 15, wherein said probe control mechanism includes:
a probe seal having a rotatable inner cylinder connected to said main portion of said probe, said inner cylinder being rotatable around a rotary axis, the axis of said main portion of said probe being offset from the rotary axis to result in movement of said main portion along the predetermined measuring track when said inner cylinder rotates;
a guiding component disposed on said probe seal and disposed parallel to said probe;
a sliding component slidably disposed on said guiding component and connected to said probe;
an elevating motor disposed on said probe seal and connected to said sliding component for controlling raising and lowering of said probe; and
a rotating motor disposed on said sliding component and connected to said probe for controlling rotation of said main portion of said probe around the axis of said main portion.

18. The probe system as claimed in claim 17, wherein said probe control mechanism further includes a position measuring device for measuring vertical displacement of said probe.

19. The probe system as claimed in claim 18, further comprising a force sensor disposed on said probe for determining whether said tip of said probing portion comes into contact with the solid-liquid interface.

20. The probe system as claimed in claim 16, wherein said probe control mechanism includes a position measuring device for measuring vertical displacement of said probe.
